(19) United States
(12) Patent Application Publication
(10) Pub. No.: US 2020/0392645 A1
(43) Pub. Date: Dec. 17, 2020

(54) HYDRIDE VAPOR PHASE EPITAXY REACTORS

(71) Applicant: Alliance for Sustainable Energy, LLC, Golden, CO (US)

(72) Inventors: Kevin Louis SCHULTE, Denver, CO (US); Aaron Joseph PTAK, Littleton, CO (US); John David SIMON, Austin, TX (US)

(21) Appl. No.: 16/902,117

(22) Filed: Jun. 15, 2020

Related U.S. Application Data
(60) Provisional application No. 62/861,126, filed on Jun. 13, 2019.

(51) Int. Cl. C30B 25/12; C30B 25/10

(52) U.S. Cl. CPC C30B 25/12; C30B 29/42; C30B 25/10

(57) ABSTRACT

Disclosed herein are novel hydride vapor phase epitaxy reactors and methods of use.

### CROSS-REFERENCE TO RELATED APPLICATIONS

This application claims priority under 35 U.S.C. § 119 to U.S. Provisional Patent Application No. 62/861,126, filed on 13 Jun. 2019, the contents of which are hereby incorporated by reference in their entirety.

### CONTRACTUAL ORIGIN

The United States Government has rights in this invention under Contract No. DE-AC36-08GO28308 between the United States Department of Energy and Alliance for Sustainable Energy, LLC, the Manager and Operator of the National Renewable Energy Laboratory.

### BACKGROUND

Effective hydride vapor phase epitaxy (HVPE) reactors require moving parts that can go to high temperatures and be in contact with HCl gas. The movement of a platen containing the growth substrate(s) must also be precise enough to control the speed and position of the substrates within the reactor. Single chamber HVPE reactors exist. But an in-line HVPE reactor with multiple chambers is not available in the market. There are many engineering challenges associated with an in-line reactor (some of them highlighted above) which has limited the development of this technology, as well as little market push for it.

### SUMMARY

In an aspect, disclosed herein are HVPE reactors that are improved over existing designs.

In an aspect disclosed herein is a reactor capable of the deposition of at least one layer of a semiconductor device by using hydride vapor phase epitaxy (HVPE), wherein the reactor has a substrate platen capable of movement by translation means; and wherein the substrate platen is fixed to the translation means. In an embodiment, the platen comprises a mesh structure. In an embodiment, the platen allows process gases to flow to a substrate fixed to the platen. In another embodiment, the platen comprises quartz. In an embodiment, the mesh platen has a thermal mass that is less than a comparable solid platen. In an embodiment, the substrate platen is fixed to the translation means through wires. In an embodiment, the wires are ceramic or glass. In yet another embodiment, the translation means comprise spools wherein the unspooling or spooling of the wires causes the position of the platen to change. In an embodiment, the reactor comprises multiple spools wherein the rotation of a first spool in one direction moves the platen in a first direction and wherein the rotation of a second spool moves the platen in a second direction, and wherein the rotation of a third spool moves the platen in a third direction. In another embodiment, the platen slides in and out of the reactor through slots in the wall of the reactor. In an embodiment, the translation means are bearings. In an embodiment, the bearings comprise quartz or alumina. In another embodiment, the reactor further comprises heating means wherein the heating means are independent radio-frequency coils (RF coils). In an embodiment, the independent radio-frequency coils are capable of selectively heating different parts of the reactor. In embodiment, the reactor comprises multiple reaction chambers and multiple platens wherein an individual platen is capable of translation in between the multiple reaction chambers. In another embodiment, the reactor is configured to deliver AsH₃ directly to the substrate platen. In an embodiment, the reactor is configured to deliver uncracked AsH₃.

In an aspect, disclosed herein is a reactor capable of the deposition of at least one layer of a semiconductor device by using hydride vapor phase epitaxy (HVPE), wherein the reactor comprises multiple reaction chambers; and wherein the reactor has a substrate platen capable of movement by translation means; and wherein the substrate platen is fixed to the translation means; and wherein the platen can be moved between the multiple chambers. In an embodiment, the reactor has different reaction chambers that are capable of operating at different temperatures with different reactants.

In another aspect, disclosed herein is a reactor that is capable of the deposition of at least one layer of a semiconductor device by using hydride vapor phase epitaxy (HVPE), wherein the reactor has a substrate platen that is made out of mesh, and wherein substrates are fixed to the platen and wherein the platen allows process gases to flow to the substrate; and wherein a group III precursor and a group V precursor are delivered through separate ports which are heated independently of each other and independently of a deposition zone.

### DESCRIPTION OF THE DRAWINGS

Exemplary embodiments are illustrated in referenced figures of the drawings. It is intended that the embodiments and figures disclosed herein are to be considered illustrative rather than limiting.

FIG. 1 depicts an exemplary HVPE reactor design.

FIG. 2 depicts an exemplary HVPE reactor design.

FIG. 3 depicts an exemplary HVPE reactor design.

FIG. 4 depicts an exemplary HVPE reactor design.

FIG. 5 depicts an exemplary HVPE reactor design.

FIG. 6 depicts an exemplary HVPE reactor design.

FIG. 7 depicts an exemplary HVPE reactor design.

FIG. 8 depicts an exemplary HVPE reactor design.

FIG. 9 depicts an exemplary HVPE reactor design.

FIG. 10 depicts an exemplary HVPE reactor design.

### DETAILED DESCRIPTION

Disclosed herein are improved and novel HVPE reactors.

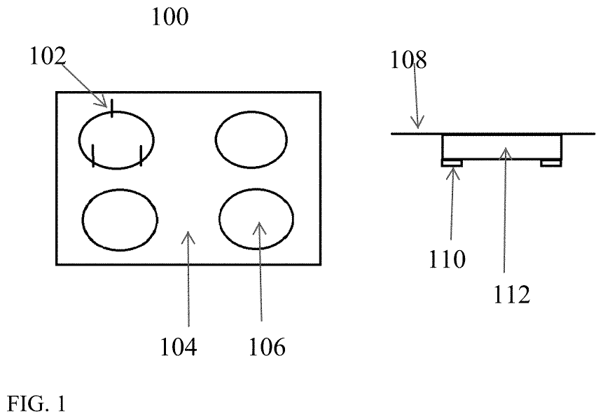

As depicted in FIG. 1, (100) in an embodiment, a HVPE reactor has a substrate platen (104) that is made out of a mesh. In an embodiment, the platen is made out of quartz. Substrates can sit either on top of the platen and the substrates (106) are held in place on the platen by some means such as clips, or the like (102). In an embodiment, the substrates can hang upside down on feet to keep them from falling through the mesh platen. In an embodiment, the mesh platen allows process gases to flow through easier and also decrease the rendered thermal mass of the platen when compared to a solid platen. In an embodiment, the platen is connected to a wire (108) or system of wires. In an embodiment a hanging platen (112) has feet (110) associated with the platen.

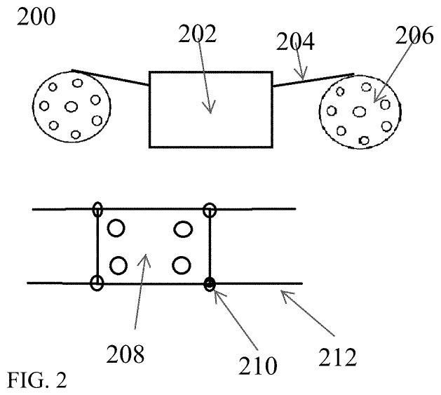

As depicted in FIG. 2 (200) the motion of a platen (202) within a HVPE reactor can be controlled by wire means (204). In an embodiment, ceramic, glass or other non-corrosive wires could be used to move the substrates platen from chamber to chamber of a HVPE reactor. In an embodiment, the wires would have low thermal mass to avoid temperature swings. The wires could be used to move the platen in any given direction, into and out of the process box of a given HVPE reactor. As depicted in FIG. 2, the wires are wrapped around a spool (206) such that the rotation of the spool in one direction moves the wire (and thus the platen to which it is attached) in a first direction and the rotation of a separate, analogous spool can move the platen in a second direction. The number of spools and wires can be expanded to any orientation, thus allowing the precise movement of a platen containing substrates on which HVPE growth takes place within a HVPE reactor.

As further depicted in FIG. 2, the platen (208) could clip (210) to two guide wires (212) so there is no slippage of the platen. In another embodiment, the wire system accommodates hanging wires.

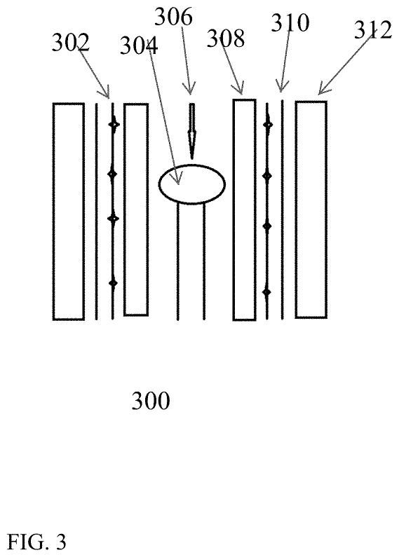

As depicted in FIG. 3, a stainless steel HVPE reactor (300) has corrosion resistant inserts. In an embodiment, and as depicted in FIG. 3, the stainless steel (or other corrosion resistant material) HVPE reactor contains in the middle of a reaction chamber, a platen (304) having substrate for HVPE growth. The platen is exposed to gas flow (306) that contains a carrier gas having the substrate or substrates to be used in the epitaxial growth. Moving from the interior to the exterior of the HVPE reactor, it further comprises a quartz or other insert (308) that creates a chamber surrounding the platen with substrate. Moving further outwards from the quartz or other insert, some heating means (302) surrounds the quartz inserts. The heating means may be, for example, an optical or other heating method. Moving further out from the heating means, a layer of reflector material (310) exists surrounding the heating means. In an embodiment, a cooling jacket (312) surrounds the chamber created by the reflector and the cooling jacket is surrounded by an exterior facing surface, such as stainless steel or another material. In an embodiment, the cooling jacket is capable of having water flow through the jacket which provides cooling to the HVPE reaction chamber as needed. In an embodiment, stainless steel is used as a process gas seal with gas localization to keep process gases away from the reaction chamber. In an embodiment, the inner quartz inserts don't need to be vacuum tight, but merely need to contain the process gases. In an embodiment the inner quartz inserts are vacuum tight.

Three-Chamber HVPE Reactor

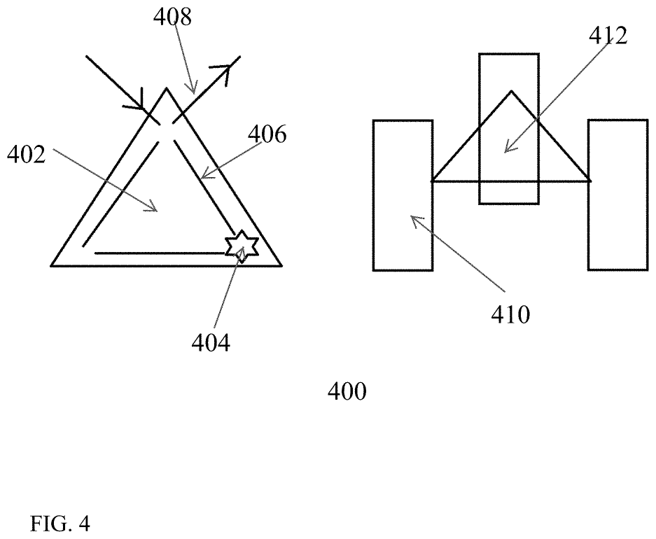

In an embodiment, disclosed herein is a three-chamber HVPE reactor. As depicted in FIG. 4 (400), as top view (402) and a side view (412) of the three-chamber HVPE reactor consists of a star shaped platen (404) with tracks (406) between each of the three reaction chambers (410). In an embodiment, the number of chambers may be 2, 3, 4, or more. In the case of a three-chamber HVPE reactor, the platen of substrates can be transferred mechanically in any order, such as from chamber 1 to 2, 1 to 3, or 2 to 3. In an embodiment, the platen is moved by transfer arms (408) or wires which can propel platens having shapes that allow for different growth of different materials within a given HVPE reaction chamber. As an example, and as depicted in FIG. 4, a platen may be star shape. The star shape platen could be rotated to expose an arm of the platen to a given HVPE reaction chamber of the multiple-chambered HVPE reactor. In another embodiment, the HVPE reaction chambers are separated by thin horizontal, triangular transfer slots which can be designed to help keep the platen on a track.

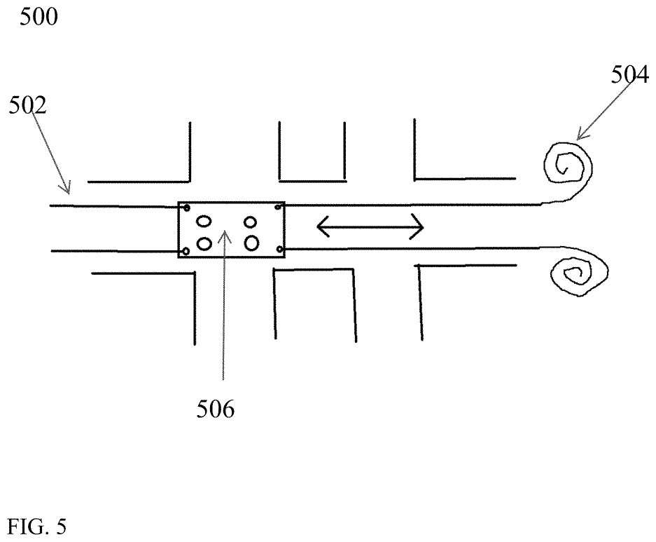

As depicted in FIG. 5 (500), a transfer mechanism of a platen (506) within an exemplary multi-chambered HVPE reactor (502) transfers a platen between the reaction chambers by using wires attached to the platen. In an embodiment, the wires that are attached to the platen are also attached to a spool (504); and as described above, the rotation of the spool causes the wire that is attached to the platen to move the platen in a given direction. Thus, through the different rotations of various spools containing wires attached to the platen, the platen may be moved from chamber to chamber of the multi-chambered HVPE reactor with extreme precision. In an embodiment, the wires are in tension and spooled on each side of the platen. In an embodiment, a motor can drive the wires and then the platen so that it moves laterally between chambers, see FIG. 5.

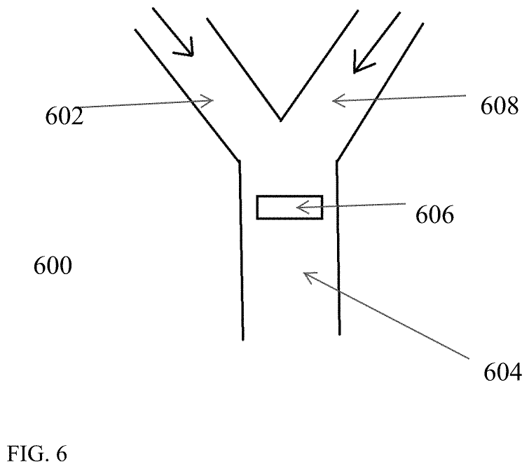

As depicted in FIG. 6 (600), a HVPE reactor (604) in which group III (608) and group V (602) precursors are delivered in separate ports which are heated independently of each other and independently of the deposition zone (606).

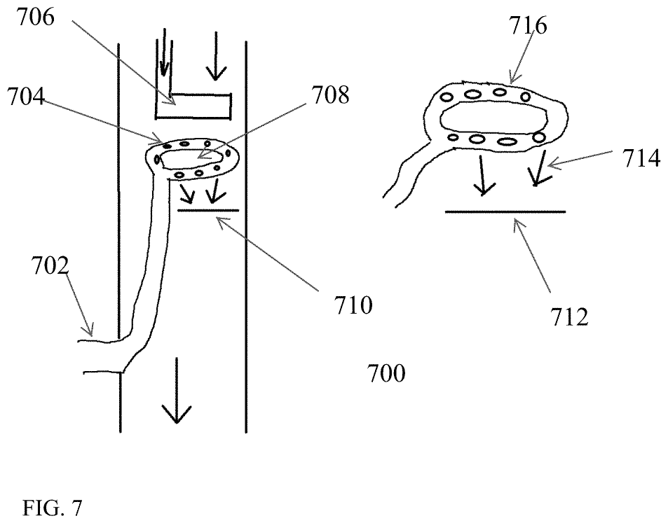

As depicted in FIG. 7 (700), a HVPE reactor may be configured such that a group V precursor is delivered into a high velocity injector (708) with nozzles (704 and 716) designed to promote high velocity and uniformity (714). In an embodiment, AsH₃ comes in from an inlet tube (702) directed into the reactor so that it only passes through the lower temperature region of the reactor where growth occurs. In an embodiment, as depicted in FIG. 7, the holes (704 and 716) that distribute the gas containing the substrate are angle to promote uniform gas distribution upon the platen (710 and 712) containing the growth substrate.

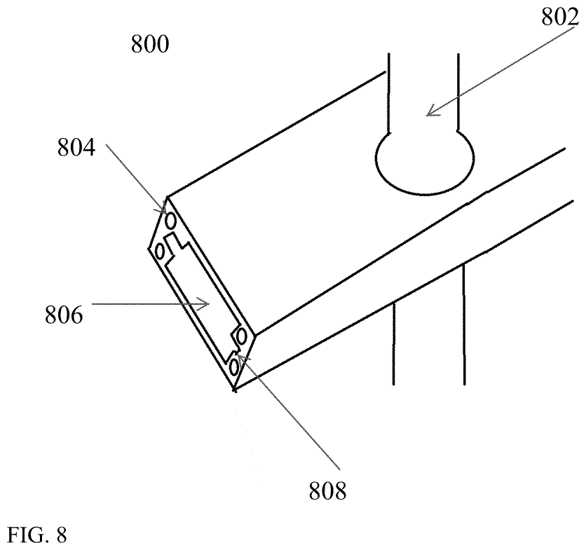

As depicted in FIG. 8 (800), a HVPE reactor (802) is disclosed in which a platen slides in and out through a slotted reactor on bearings (804) such as quartz or alumina. In an embodiment, as depicted in FIG. 8, the HVPE reactor has thick sides (808) that can help insulate the reaction chamber (806).

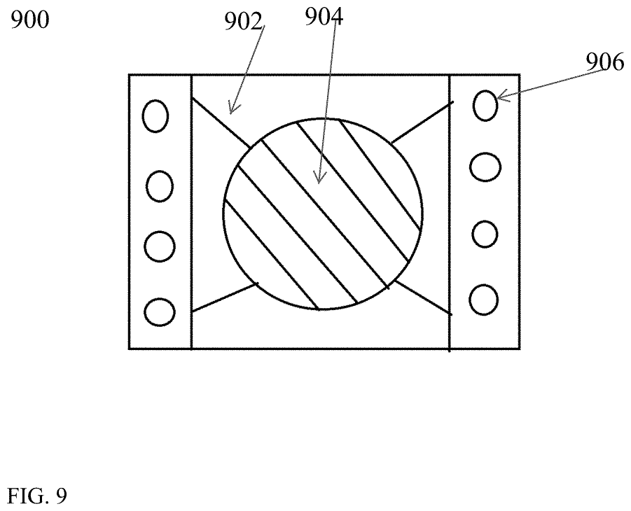

As depicted in FIG. 9 (900), a HVPE reactor may be configured such that a platen (904) moves in and out through a reaction chamber (902) on bearings (906) that contact the platen and allow it to move through the reaction chamber. In an embodiment, the platen can hold one or multiple wafers with mostly air channels around it.

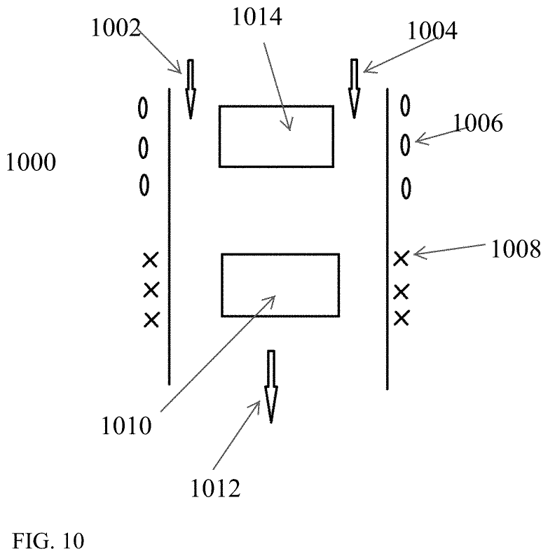

As depicted in FIG. 10 (1000), a HVPE reactor that allows for uncracked AsH₃ (1002 and 1004) to react with the substrate (1010) is disclosed. As depicted in FIG. 10, the HVPE reactor is configured to have gases (1002 and 1004) flow through the reaction chamber while independent radio-frequency coils (RF coils) (1006 and 1008) are able to selectively heat group III sources (1010) before the products of the reactions (1012) exit the reaction chamber to a substrate.

In an embodiment, disclosed herein is a HVPE reactor in which the wafer(s) are translated between chambers using high temperature bearings on a platen. The bearings will be attached to a platen and allow to carry multiple wafers accurately and across multiple chambers while keeping the mechanical parts of the motion outside of the hot corrosive environment. The shape and bearing help align the platen in reactor chamber.

In an embodiment, disclosed herein is a HVPE reactor in which the wafer(s) are translated between chambers using high temperature wires moving across the reactor. The wires can be connected to two spools at either end of in-line reactor allowing for back and forth motion of wafer(s) while maintaining moving parts outside of hot corrosive environment.

In an embodiment, disclosed herein is a HVPE reactor compromising of three independent chambers where the wafer(s) can be translated between any of the three reactors directly. This allows for the growth of multiple layers of a semiconductor device in any chamber order the user desires. This makes it easier to keep incompatible chemistries segregated to independent chambers in a non in-line reactor.

In an embodiment, disclosed herein is a HVPE reactor where the group III metals are heated with RF coils in order to achieve independent heating/temperature of each metal and the reactor. Each group III metal source can be heated to an independent temperature by using a separate RF coil for each source. This also allows the reactor chamber to remain at a lower temperature and suppress the cracking of the AsH₃ molecule before it reaches the substrate. This will enable HVPE chemistry.

In an embodiment, disclosed herein is a mesh holder for wafer(s) inside an in-line HVPE reactor. This can provide mechanical support to a substrate(s) while allowing reactant gases to flow around it. This will allow uniform growth over multiple wafers.

In an embodiment, disclosed herein is a method to introduce uncracked AsH₃ into a growth chamber. AsH₃ is typically introduced through the ‘hot’ zone of an HVPE reactor for simplicity. But if it is introduced directly into the substrate location it can bypass the ‘hot’ zone and maximize the amount of uncracked AsH₃ that is delivered to the substrate, enabling HVPE chemistry. This method can include a special injector that sits just above the substrate and is perforated to ensure uniform, high velocity AsH₃ delivery with minimal AsH₃ cracking. The inlet of this injector can come in through the cooler deposition zone and always remain in that zone.

In an embodiment, disclosed herein is a means to build a modular HVPE reactor while maintaining good seals to the outside atmosphere. The reactor will be compromised of a heated insert (e.g. Quartz) that is surrounded by a water-cooled stainless sealing volume. This allows for the reactor inserts to be heated and carry the corrosive gases need in HVPE while the seals to the outside are made in the water-cooled stainless. This can be repeated over multiple inserts to build a modular reactor and seals made from stainless to stainless.

In an embodiment, disclosed herein is an effective way to translate wafers through a hot corrosive environment is needed to build an inline reactor. This requires moving parts that can go to high temperatures and be in contact with HCl gas. The movement must also be precise to control the speed and position of the substrates within the reactor.

In an embodiment, disclosed herein is an effective way to translate wafers through a hot corrosive environment is needed to build an inline reactor. This requires moving parts that can go to high temperatures and be in contact with HCl gas. The movement must also be precise to control the speed and position of the substrates within the reactor. This reactor also allows for more flexibility in the design of structures being grown on it as the wafer is not constricted to which reactor it has to go next.

In an embodiment, disclosed herein is a HVPE reactor using one heater to heat the reactor and the group III metals makes it difficult to independently control the conversion reactions of the different metals. With separate heaters you can manipulate the conversion mechanisms of each metal chloride without affecting the process related to the other metals.

In an embodiment, disclosed herein is a holding a wafer in a solid platen will disturb the gas flow in any deposition reactor. By using a mesh holder allows for gas to flow around substrate(s) and still provide mechanical support.

In an embodiment, disclosed herein is a method for the growth of GaAs by use of cracked arsine in conventional HVPE results in slow growth rates. By delivering uncracked arsine to the surface higher growth rates and hence higher throughputs can be achieved.

In an embodiment, disclosed herein are HVPE reactors require high temperature and corrosive gases. This is not conducive to good seals to keep reactants inside while keeping atmospheric gases out. Most vacuum seals cannot go above 300° C. This makes making a modular system where the temperature needs to be above 600° C. and still vacuum sealed very challenging.

We claim:

1. A reactor capable of the deposition of at least one layer of a semiconductor device by using hydride vapor phase epitaxy (HVPE), wherein the reactor has a substrate platen capable of movement by translation means; and wherein the substrate platen is fixed to the translation means.

2. The reactor of claim 1 wherein the platen comprises a mesh structure.

3. The reactor of claim 2 wherein the platen allows process gases to flow to a substrate fixed to the platen.

4. The reactor of claim 1 wherein the platen comprises quartz.

5. The reactor of claim 2 wherein the mesh platen has a thermal mass that is less than a comparable solid platen.

6. The reactor of claim 1 wherein the substrate platen is fixed to the translation means through wires.

7. The reactor of claim 6 wherein the wires are ceramic or glass.

8. The reactor of claim 6 wherein the translation means comprise spools wherein the unspooling or spooling of the wires causes the position of the platen to change.

9. The reactor of claim 8 comprising multiple spools wherein the rotation of a first spool in one direction moves the platen in a first direction and wherein the rotation of a second spool moves the platen in a second direction, and wherein the rotation of a third spool moves the platen in a third direction.

10. The reactor of claim 1 wherein the platen slides in and out of the reactor through slots in the wall of the reactor.

11. The reactor of claim 1 wherein the translation means are bearings.

12. The reactor of claim 11 wherein the bearings comprise quartz or alumina.

13. The reactor of claim 1 further comprising heating means wherein the heating means are independent radio-frequency coils (RF coils).

14. The reactor of claim 13 wherein the independent radio-frequency coils are capable of selectively heating different parts of the reactor.

15. The reactor of claim 14 comprising multiple reaction chambers and multiple platens wherein an individual platen is capable of translation in between the multiple reaction chambers.

16. The reactor of claim 1 wherein the reactor is configured to deliver AsH₃ directly to the substrate platen.

17. The reactor of claim 1 configured to deliver uncracked AsH₃.

18. A reactor capable of the deposition of at least one layer of a semiconductor device by using hydride vapor phase epitaxy (HVPE), wherein the reactor comprises multiple reaction chambers; and wherein the reactor has a substrate platen capable of movement by translation means; and wherein the substrate platen is fixed to the translation means; and wherein the platen can be moved between the multiple chambers.

19. The reactor of claim 18 wherein the different reaction chambers are capable of operating at different temperatures with different reactants.

20. A reactor capable of the deposition of at least one layer of a semiconductor device by using hydride vapor phase epitaxy (HVPE), wherein the reactor has a substrate platen that is made out of mesh, and wherein substrates are fixed to the platen and wherein the platen allows process gases to flow to the substrate; and wherein a group III precursor and a group V precursor are delivered through separate ports which are heated independently of each other and independently of a deposition zone.
